(19) United States
(12) Patent Application Publication
(10) Pub. No.: US 2015/0017904 A1
(43) Pub. Date: Jan. 15, 2015

(54) SERVER RACK AND FAN APPARATUS

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: AN-GANG LIANG, Shenzhen (CN); MING-YU LIU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/951,413

(22) Filed: Jul. 25, 2013

(30) Foreign Application Priority Data
Jul. 12, 2013 (CN) 2013102915000

(51) Int. Cl. H05K 7/20

(52) U.S. Cl. CPC H05K 7/20718
USPC 454/184; 415/182.1

(57) ABSTRACT

A fan apparatus includes a bracket, a fan module installed in the bracket, and a cable management assembly. The bracket defines an opening. The fan module includes a connector received in the opening. The cable management assembly includes a cover detachably mounted to the bracket to cover the opening, and a cable management member installed on the cover. The connector is mounted on an inner side of the cover by the cable management member.

### BACKGROUND

1. Technical Field

The disclosure relates to server racks, and more particularly, to a server rack with a fan apparatus.

2. Description of Related Art

Racks for electronic devices, such as server racks, use heat dissipation assemblies for dissipating heat generated by the servers therein, thus preventing the servers from becoming overheated. The heat dissipation assembly mainly includes a bracket mounted to the rack by screwing or clamping, and a plurality of fans mounted to the bracket. Each fan includes a connector placed between the bracket and the rack. Thus, it is inconvenient to plug and unplug the connectors.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an embodiment of a server rack, wherein the server rack includes a fan apparatus.

FIG. 2 is an exploded, isometric view of the fan apparatus of FIG. 1.

FIG. 3 is an enlarged, partially cutaway view of the fan apparatus of FIG. 2.

FIG. 4 is an assembled, isometric view of FIG. 3.

FIG. 5 is similar to FIG. 4, but viewed from another perspective.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean “at least one.”

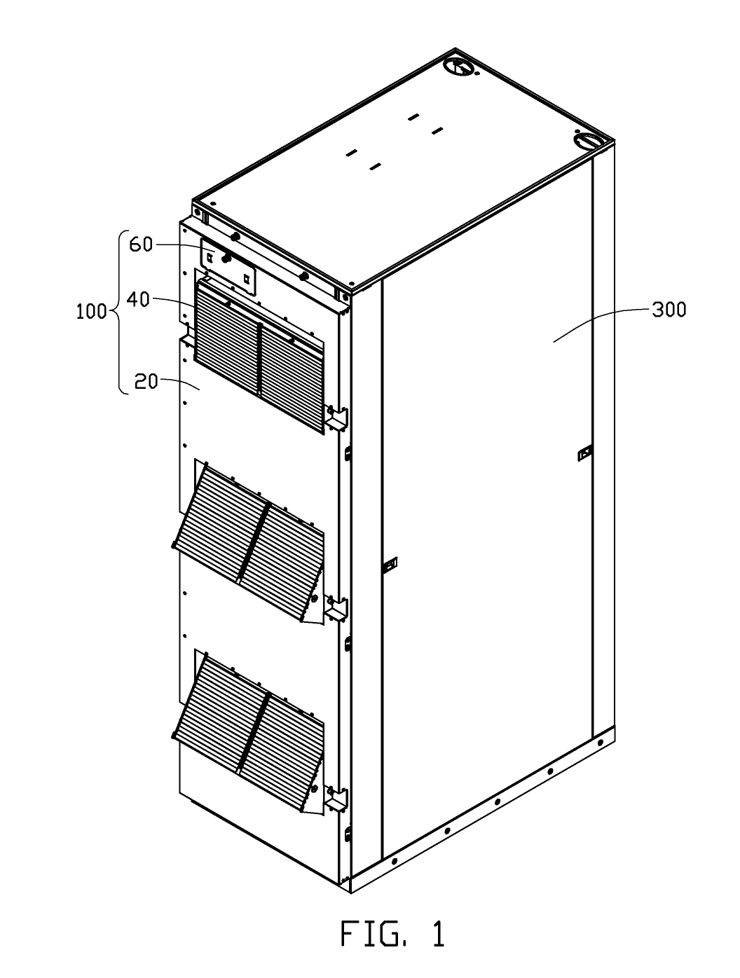

FIG. 1 shows a server rack including a rack 300 and a fan apparatus 100.

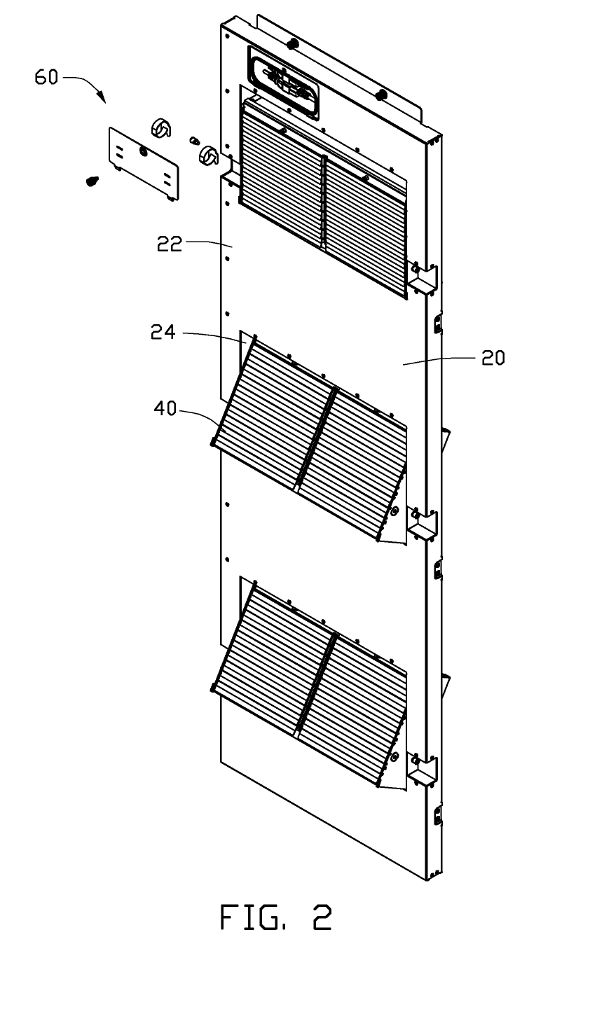

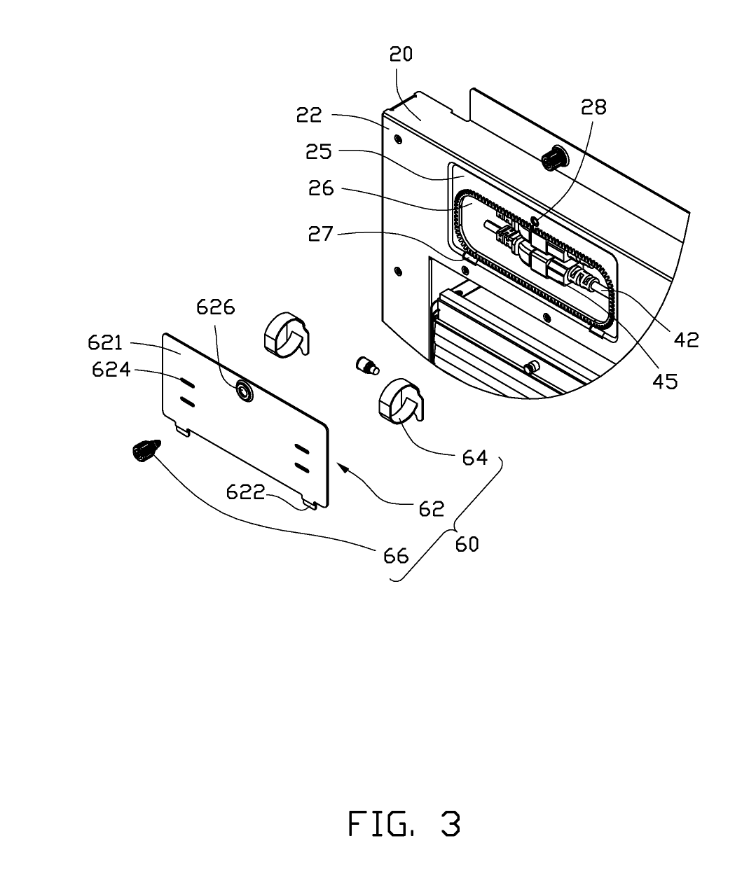

FIGS. 2 and 3 show the fan apparatus 100 including a bracket 20, a plurality of fan modules 40, and a cable management assembly 60. Each fan module 40 includes a cable 42 and a connector 45 connected to a distal end of the cable 42.

The bracket 20 includes a rectangular rear plate 22. The rear plate 22 defines a plurality of receiving spaces 24 arranged along a lengthwise direction of the rear plate 22. The fan modules 40 are pivotably received in the receiving spaces 24. A rectangular inset portion 25 is formed in an upper portion of the rear plate 22. An inner wall of the inset portion 25 defines a rectangular opening 26 and a fastening hole 28 above the opening 26. A junction of the inset portion 25 and the rear plate 22 defines two latching holes 27 below the opening 26.

The cable management assembly 60 includes a cover 62, two cable management members 64, and a fastener 66.

The cover 62 includes a rectangular plate 621. Two L-shaped latching pieces 622 extend down from a bottom side of the plate 621. Two opposite ends of the plate 621 each define two spaced through slots 624. A middle of an upper portion of the cover 62 defines a through hole 626 opposite to the latching pieces 622.

In the embodiment, each cable management member 64 is a circular band, and the fastener 66 is a screw.

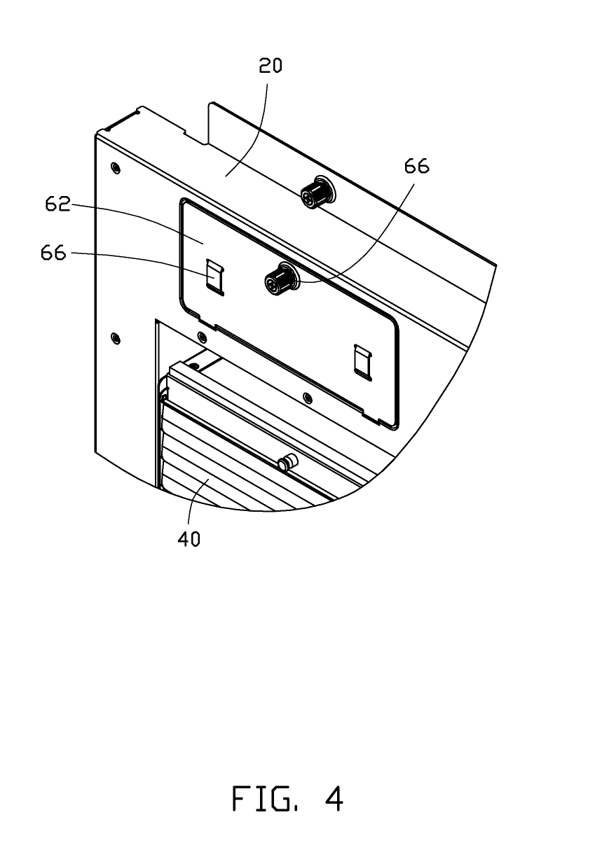

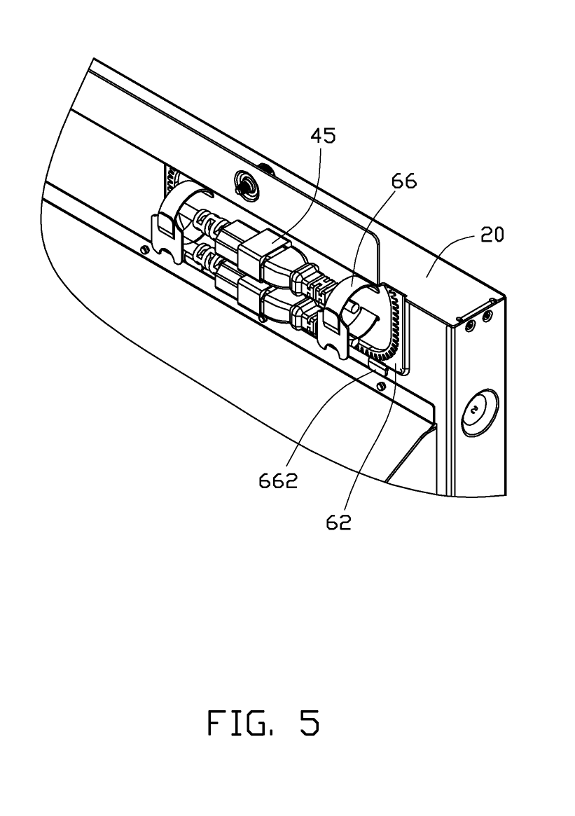

FIGS. 4 and 5 show that in use, the connectors 45 of the fan modules 40 and a connector of a power supply are extended through the opening 26 from an inside of the bracket 20. The cable management members 64 extend through the through slots 624, to fasten the cables 42 to a rear surface of the plate 621. Thus, the connectors 45 of the fan modules 40 and the connector of the power supply are mounted on the rear surface of the plate 621. The latching pieces 622 are latched in the latching holes 27, the cover 62 is received in the inset portion 26, and the connectors 45 are received in the opening 26. The fastener 66 extends through the through hole 626 of the cover 62, to be screwed into the fastening hole 28 of the bracket 20.

The fan apparatus 100 is mounted to a rear side of the rack 300 by screwing or clamping. To unplug the connectors 45 from the connector of the power supply, the fastener 66 is released from the fastening hole 28 and the cable management assembly 60 is disengaged from the inset portion 25. Thus, the connectors 45 are expediently operated, without disengaging the bracket 20 from the rack 300.

It is to be understood, however, that even though numerous characteristics and advantages of certain embodiments have been set forth in the foregoing description, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A fan apparatus, comprising:
a bracket defining an opening;
a fan module installed in the bracket and comprising a connector received in the opening; and
a cable management assembly comprising a cover detachably mounted to the bracket to cover the opening, and a cable management member installed on the cover;
wherein the connector is mounted on an inner side of the cover by the cable management member.

2. The fan apparatus of claim 1, wherein an inset portion is formed on the bracket, the opening is defined in an inner wall of the inset portion.

3. The fan apparatus of claim 2, wherein the inset portion defines a latching hole below the opening, the cover comprises a plate received in the inset portion and a latching piece extending out from the plate to latch in the latching hole.

4. The fan apparatus of claim 3, wherein the inset portion defines a fastening hole above the opening, the plate defines a through hole opposite to the latching piece, the cable management assembly further comprises a fastener extended through the through hole to latch in the fastening hole.

5. The fan apparatus of claim 3, wherein the plate defines two spaced through slots, the cable management member extends through the through slots to mount the connector on an inner side of the plate.

6. The fan apparatus of claim 1, wherein the cable management member is a circular band.

7. A server rack, comprising:
a rack; and
a fan apparatus comprising:
a bracket mounted to the rack and defining an opening;
a fan module installed in the bracket and comprising a connector received in the opening; and
a cable management assembly comprising a cover detachably mounted to the bracket to cover the opening, and a cable management member installed on the cover;
wherein the connector is mounted on an inner side of the cover by the cable management member.

8. The server rack of claim 7, wherein an inset portion is formed on the bracket, the opening is defined in an inner wall of the inset portion.

9. The server rack of claim 8, wherein the inset defines a latching hole below the opening, the cover comprises a plate received in the inset portion and a latching piece extending out from the plate to latch in the latching hole.

10. The server rack of claim 9, wherein the inset portion defines a fastening hole above the opening, the plate defines a through hole opposite to the latching piece, the cable management assembly further comprises a fastener extended through the through hole to latch in the fastening hole.

11. The server rack of claim 9, wherein the plate defines two spaced through slots, the cable management member extends through the through slots to mount the connector on an inner side of the plate.

12. The server rack of claim 7, wherein the cable management member is a circular band.
